(19) United States
(12) Patent Application Publication
(10) Pub. No.: US 2024/0393683 A1
(43) Pub. Date: Nov. 28, 2024

(54) SUBSTRATE PROCESSING SYSTEM AND ARTICLE MANUFACTURING METHOD

(71) Applicant: CANON KABUSHIKI KAISHA, Tokyo (JP)

(72) Inventor: KENJI YAEGASHI, Tochigi (JP)

(21) Appl. No.: 18/668,573

(22) Filed: May 20, 2024

(30) Foreign Application Priority Data
May 24, 2023 (JP) 2023-085704

(51) Int. Cl. G03F 7/00

(52) U.S. Cl. CPC G03F 7/0035; G03F 7/70725; G03F 7/7085

(57) ABSTRACT

A substrate processing system includes a plurality of operation modules each configured to perform operations of bringing a curable composition on a substrate into contact with a mold and separating a cured product of the curable composition and the mold from each other; and one or a plurality of processing modules configured to be inserted/removed into/from each of the plurality of operation modules by a pivoting operation, wherein the one or the plurality of processing modules perform a process for shaping a curable composition on a substrate by using a mold in each of the plurality of operation modules, and the process includes at least one of a chemical process and a measurement process.

### BACKGROUND OF THE INVENTION

### Field of the Invention

The present invention relates to a substrate processing system and an article manufacturing method.

### Description of the Related Art

Some substrate processing system includes a plurality of processing units and processes a substrate by using the plurality of processing units. For example, Japanese Patent Laid-Open No. 2005-353969 discloses an exposure apparatus that includes an exposure stage unit and an alignment stage unit and concurrently executes an exposure operation and an alignment operation.

### SUMMARY OF THE INVENTION

The present invention provides a technique advantageous in simplifying the arrangement of a substrate processing system that concurrently processes two or more substrates.

One of aspect of the present invention provides a substrate processing system comprising: a plurality of operation modules each configured to perform operations of bringing a curable composition on a substrate into contact with a mold and separating a cured product of the curable composition and the mold from each other; and one or a plurality of processing modules configured to be inserted/removed into/from each of the plurality of operation modules by a pivoting operation, wherein the one or the plurality of processing modules perform a process for shaping a curable composition on a substrate by using a mold in each of the plurality of operation modules, and the process includes at least one of a chemical process and a measurement process.

Further features of the present invention will become apparent from the following description of exemplary embodiments with reference to the attached drawings.

### BRIEF DESCRIPTION OF THE DRAWINGS

FIG. 1 is a view showing the arrangement of a substrate processing system according to one embodiment;

FIGS. 2A to 2C are views exemplarily showing a procedure for planarization processing;

FIGS. 3A to 3F are views for explaining the operation of the substrate processing system in planarization processing;

FIG. 4 is a view for explaining the operation of the substrate processing system in planarization processing; and

FIG. 5 is a view for exemplarily explaining the operation of the substrate processing system according to one embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

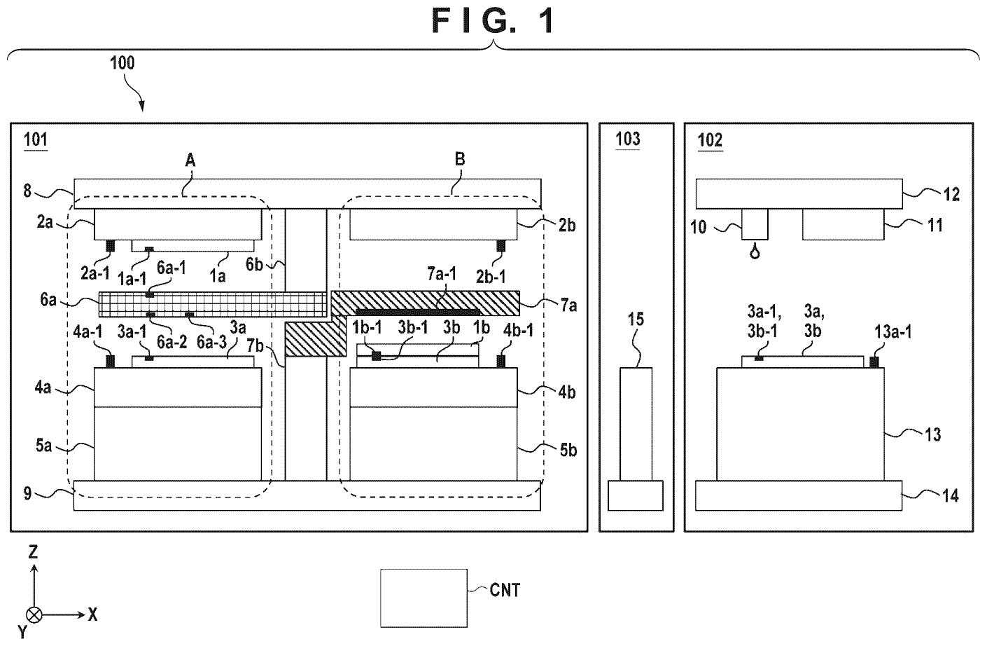

FIG. 1 schematically shows the arrangement of a substrate processing system 100 according to one embodiment of the present disclosure. The substrate processing system 100 is configured to perform a shaping process of shaping curable compositions on substrates 3a and 3b. The substrate processing system 100 can include, for example, a processing station 101, a processing station 102, and a conveying mechanism 103. The processing station 102 executes an application step of applying curable compositions onto the substrates 3a and 3b. The processing station 101 can execute a shaping process of shaping curable compositions on the substrates 3a and 3b. The shaping process can include a contact step, a curing step, and a separation step. The contact step can include bringing curable compositions on the substrates 3a and 3b into contact with molds 1a and 1b. The curing step can include curing the curable compositions while the curable compositions on the substrates 3a and 3b are in contact with the molds 1a and 1b. The separation step can include separating the cured products of the curable compositions from the molds 1a and 1b after the curing step. Note that the substrates 3a and 3b each are expressed as a substrate 3 when expressed without being discriminated from each other. Likewise, the molds 1a and 1b each are expressed as a mold 1 when expressed without being discriminated from each other.

In the specification and the accompanying drawings, directions will be indicated on an XYZ coordinate system in which directions parallel to the surface of the substrate 3 are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis direction, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Alignment means controlling a position and/or a tilt. Alignment can include controlling the position and/or the posture of at least one of the substrate 3 and the mold 1. In addition, alignment can include control to change the position or the shape of at least one of the substrate 3 and the mold 1.

As the curable composition, a curable composition to be cured by receiving curing energy is used. Examples of the curing energy are an electromagnetic wave and heat. As the electromagnetic wave, for example, light selected from the wavelength range of 10 nm (inclusive) to 1 mm (inclusive) is used. Examples of the electromagnetic wave are infrared light, a visible light beam, and ultraviolet light. The curable composition is a composition cured by irradiation with light or heating. Among these compositions, a photo-curable material cured by light contains at least a polymerizable compound and a photopolymerization initiator and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable material may be applied in a film shape onto the substrate by a spin coater or a slit coater. The curable material may be applied, onto the substrate, in a droplet shape or in an island or film shape formed by connecting a plurality of droplets using a liquid injection head. The viscosity (the viscosity at 25° C.) of the curable material is, for example, 1 mPa·s (inclusive) to 100 mPa·s (inclusive).

The mold 1 can have, for example, a flat surface. The substrate processing system 100 is configured as a planarization apparatus that forms a planarized film made of the cured product of the curable composition by bringing the curable composition on the substrate 3 into contact with the mold 1 and curing the curable composition. The planarization apparatus can collectively form, for example, a planarized film on almost the entire region of each substrate 3. Alternatively, the substrate processing system 100 can be configured as a pattern forming apparatus (for example, an imprint apparatus) that uses the mold 1 having a pattern and transfers the pattern onto a curable composition on the substrate 3. The pattern forming apparatus may separately form a pattern on each partial region of the substrate 3 or may collectively form a pattern on a plurality of partial regions. A pattern to be formed may be an optical element or a micro-circuit.

The following is a description of the substrate processing system 100 as a planarization apparatus as an example. However, the substrate processing system 100 may be configured as a process apparatus.

The substrate 3 can be, for example, a silicon wafer, but this is not exhaustive. The substrate 3 can be arbitrarily selected from, for example, substrates known as semiconductor device substrates such as aluminum, a titanium-tungsten alloy, an aluminum-silicon alloy, an aluminum-copper-silicon alloy, silicon oxide, and silicon nitride. The substrate 3 to be used may be a substrate whose adhesiveness to a curable composition is improved by forming an adhesive layer by surface treatment such as a silane coupling process, a silazane process, or thin organic film formation. The substrate 3 can be a circular substrate having a diameter of 300 mm, but this is not exhaustive.

As energy for curing a curable composition, for example, light is used. In this case, the mold 1 is formed of a material that transmits the light. The mold 1 is formed of, for example, at least one of the following materials: glass; quartz; a light-transmitting resin such as polymethly methacrylate (PMMA) or polycarbonate resin; a transparent metal deposited film; a flexible film made of, for example, dimethylpolysiloxane; a photo-curable film; and a metal film. For example, the mold 1 can be a circular mold having a diameter of 300 nm or more and 500 mm or less, but this is not exhaustive. The thickness of the mold 1 can be, for example, 0.25 mm or more and 2 mm or less but is not limited to this. As a curable composition, a UV curable liquid when UV light is used as curing energy. The curable composition can be a monomer such as acrylate or methacrylate.

As described above, the substrate processing system 100 can include the processing station 101, the processing station 102, and the conveying mechanism 103. The molds 1a and 1b can respectively have mold marks 1a-1 and 1b-1. The substrates 3a and 3b can respectively have substrate marks 3a-1 and 3b-1. The processing station 101 can include first operation module A and second operation module B as a plurality of operation modules each performing operations of bringing a curable composition on the substrate 3 into contact with the mold 1 and separating the cured product of the curable composition from the mold 1.

First operation module A can include a mold head 2a that holds the mold 1a, a substrate fine moving stage mechanism 4a, and a substrate coarse moving stage mechanism 5a. Second operation module B can include a mold head 2b that holds the mold 1b, a substrate fine moving stage mechanism 4b, and a substrate coarse moving stage mechanism 5b. The mold heads 2a and 2b can respectively have mold reference marks 2a-1 and 2b-1. The processing station 101 can include a mold head base 8 that supports the mold heads 2a and 2b and a stage base 9 that supports the substrate coarse moving stage mechanisms 5a and 5b.

The processing station 101 can include a measurement module 6a and an exposure module 7a as one or a plurality of processing modules to be inserted/removed into/from each of the plurality of operation modules A and B by a pivoting operation. The measurement module 6a can be used to measure substrate reference marks 4a-1 and 4b-1 and the like. The exposure module 7a can be used to cure a curable composition between the substrate 3 and the mold 1 by exposing the curable composition to light. The measurement module 6a and the exposure module 7a are examples of a processing module that performs processing for shaping a curable composition on the substrate 3 using the mold 1, for example, at least one of a chemical process and a measurement process. The processing station 101 can include a first pivot mechanism 6b that makes the measurement module 6a pivot about the 0Z-axis and a second pivot mechanism 7b that makes the exposure module 7a pivot about the θZ-axis. The measurement module 6a can include measurement units 6a-1, 6a-2, and 6a-3 that perform measurement for positioning a substrate and a mold. The exposure module 7a can include an exposure unit 7a-1.

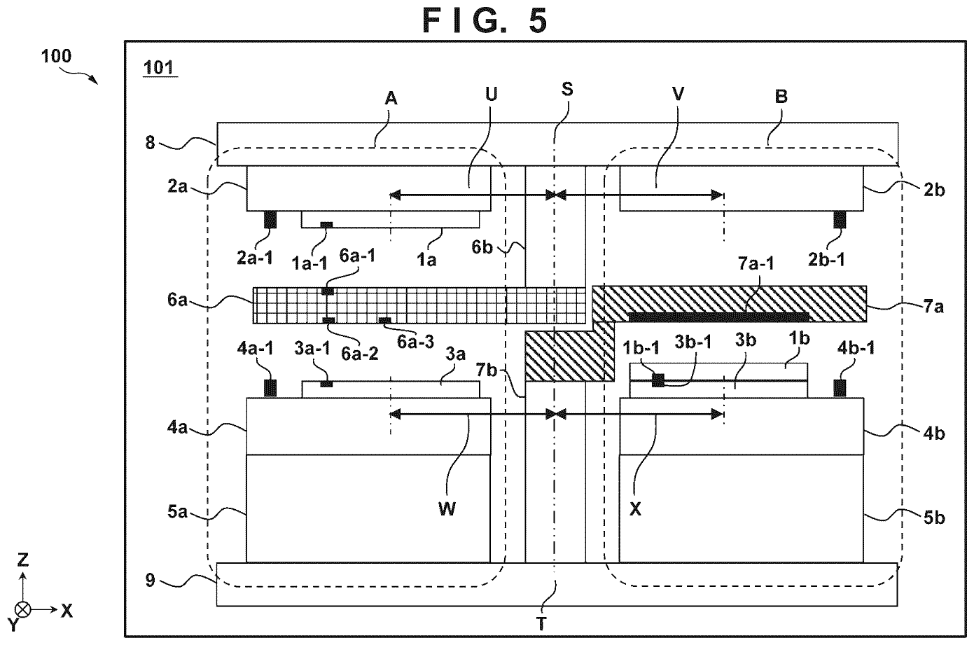

The positional relationship between the first pivot mechanism 6b and the second pivot mechanism 7b with respect to first operation module A and second operation module B will be exemplarily described with reference to FIG. 5. First of all, the central position between first operation module A and second operation module B can coincide with the central position between the molds 1a and 1b held by the mold heads 2a and 2b. The pivot axes of the first pivot mechanism 6b and the second pivot mechanism 7b can coincide with each other. Distances U and V between a pivot axis (pivot center) S of the first pivot mechanism 6b and the centers of the molds 1a and 1b held by the mold heads 2a and 2b of first operation module A and second operation module B are preferably equal to each other. Distances W and X between a pivot axis (pivot center) T of the second pivot mechanism 7b and the centers of the substrates 3a and 3b held by the substrate fine moving stage mechanisms 4a and 4b of first operation module A and second operation module B are preferably equal to each other. If U=V does not hold, at least one of the measurement module 6a, the measurement units 6a-1, 6a-2, and 6a-3, and the first pivot mechanism 6b may be provided with a translational mechanism to position the measurement units 6a-1, 6a-2, and 6a-3 by using the translational mechanism. If W=X does not hold, at least one of the exposure module 7a, the exposure unit 7a-1, and the second pivot mechanism 7b may be provided with a translational mechanism to position the exposure unit 7a-1 by using the translational mechanism.

One of the first pivot mechanism 6a and the second pivot mechanism 6b is arranged above the other of the first pivot mechanism 6a and the second pivot mechanism 6b, and the pivot axes of the first pivot mechanism 6a and the second pivot mechanism 6b can be arranged on the same straight line. In the case shown in FIG. 1, the second pivot mechanism 6b is arranged above the first pivot mechanism 6a, and the pivot axes of the first pivot mechanism 6a and the second pivot mechanism 6b are arranged on the same straight line. The first pivot mechanism 6a and the second pivot mechanism 6b may perform pivoting operations independently or simultaneously.

When three or more operation modules are arranged, the centers of them may be arranged on a circumference centered on the pivot axis of a plurality of pivot mechanisms (6a and 6b) that respectively make a plurality of processing modules (for example, the measurement module 6b and the exposure module 7b) pivot.

The exposure module 7a may have specifications that enable to irradiate the entire regions of the mold 1 and the substrate 3 with light, have specifications that enable to scan the entire regions of the mold 1 and the substrate 3 with slit light using the second pivot mechanism 7b, or other specifications.

The processing station 102 can include a dispenser 10, an alignment scope 11, a measurement base 12 that supports the dispenser 10 and the alignment scope 11, a measurement stage mechanism 13, and a measurement stage base 14 that supports the measurement stage mechanism 13. The measurement stage mechanism 13 holds the substrate 3 as a measurement target. The measurement stage mechanism 13 includes a stage, on which a substrate reference mark 13a-1 can be provided. The conveying mechanism 103 includes a conveying robot 15 that conveys the mold 1 and the substrate 3.

The substrate fine moving stage mechanisms 4a and 4b and the measurement stage mechanism 13 each include a stage having a chuck such as a vacuum chuck or an electrostatic chuck and can hold the substrate 3 with the chuck. For example, the substrate fine moving stage mechanisms 4a and 4b drive the stages having the chucks in the X-, Y-, and θZ-axis directions. The substrate coarse moving stage mechanisms 5a and 5b drive the substrate fine moving stage mechanisms 4a and 4b in the Z-axis direction. This makes it possible to position the substrate 3 in the six axis-directions. For example, the measurement stage mechanism 13 drives a stage having a chuck in the X-, Y-, and Z-axis direction. The substrate fine moving stage mechanisms 4a and 4b, the substrate coarse moving stage mechanisms 5a and 5b, and the measurement stage mechanism 13 each can include, for example, at least one of actuators such as a linear motor, a ball screw, a rack and pinion, and a cylinder.

The mold heads 2a and 2b each can include a chuck such as a vacuum chuck or an electrostatic chuck and hold the mold 1 with the chuck. The molds 1 can be driven by driving the mold heads 2a and 2b by using mold head driving units (not shown). Each mold head driving unit may be configured to drive the mold 1 with respect to a plurality of axes. Driving the mold heads 2a and 2b in the Z-axis direction can bring the molds 1 into contact with curable compositions on the substrates 3 or separate the cured products of the curable compositions on the substrates 3 from the molds 1. The mold head driving units may include mechanisms that drive the mold heads 2a and 2b with respect to axes other than the Z-axis. For example, the mold head driving units can include mechanisms that drive the mold heads 2a and 2b with respect to a plurality of axes (for example, three axes including a θX-axis, a θY-axis, and a Z-axis or six axes including an X-axis, a Y-axis, a Z-axis, a θX-axis, a θY-axis, and a θZ-axis).

The molds 1 and the substrates 3 can be loaded from outside the substrate processing system 100 into the substrate processing system 100 by the conveying robot 15 having a conveying hand and the like and transferred to the mold heads 2a and 2b, the substrate fine moving stage mechanisms 4a and 4b, and the measurement stage mechanism 13.

The dispenser 10 (supply unit) arranged on the processing station 102 can arrange or supply an uncured (liquid) curable composition onto the substrate 3. The dispenser 10 can include an orifice (nozzle) that discharges a curable material. The dispenser 10 can supply a small volume (for example, one picoliter) of curable composition onto the substrate 3 by a piezoelectric scheme or a micro solenoid scheme. The number of orifices provided in the dispenser 10 is not specifically limited and may be one or two or more. For example, the dispenser 10 has 100 or more orifices. For example, such a plurality of orifices are arranged in one or a plurality of lines.

The substrate fine moving stage mechanisms 4a and 4b or the substrate coarse moving stage mechanisms 5a and 5b of the processing station 101 may include push pins (not shown). The push pin can implement an auxiliary function when the mold 1 is separated from a curable composition on the substrate 3. For example, when the molds 1a and 1b are separated from the cured products of curable compositions, the push pins can be made to protrude from the gaps of notched portions of the substrates 3, such as notches or orientation flats, toward the molds 1. Making the push pins protrude can add force to the molds 1 in a direction in which the molds 1 are separated from the substrates 3. This can assist the separation step.

The alignment scope 11 of the processing station 102 can be used to detect the reference mark 13a-1 and the substrate marks 3a-1 and 3b-1 provided on the stage of the measurement stage mechanism 13. The alignment scope 11 can be used to detect the shapes of end portions of the substrates 3a and 3b. In addition, the alignment scope 11 can be used to detect the position and the shape of a curable material arranged by the dispenser 10. More specifically, the alignment scope 11 can be used for an alignment process of detecting the reference mark 13a-1 and a plurality of alignment marks provided on the substrates 3a and 3b and determining the positions of the substrates 3a and 3b. In addition, it is possible to determine the discharge range of a curable material by the dispenser 10 by detecting the shapes of the end portions of the substrates 3a and 3b by using the alignment scope 11 and obtaining the sizes of the substrates 3a and 3b. Furthermore, it is possible to adjust the position and the shape of a curable composition discharged by the dispenser 10 by detecting the position and the shape of the curable composition arranged by the dispenser 10 by using the alignment scope 11. The alignment scope 11 can include an optical system and an imaging system.

The measurement units 6a-1 and 6a-2 of the measurement module 6a of the processing station 101 can be used to detect the substrate reference marks 4a-1 and 4b-1 and the substrate marks 3a-1 and 3b-1 provided on the stages of the substrate fine moving stage mechanisms 4a and 4b. The measurement units 6a-1 and 6a-2 can be used to detect the shapes of the end portions of the substrates 3a and 3b, the mold reference marks 2a-1 and 2b-1 provided on the mold heads 2a and 2b, and the mold marks 1a-1 and 1b-1 provided on the molds 1a and 1b. The measurement units 6a-1 and 6a-2 can be used to detect the shapes of the end portions of the molds 1a and 1b. The measurement units 6a-1 and 6a-2 can include an optical system and an imaging system.

The measurement unit 6a-3 of the measurement module 6a of the processing station 101 can be used to detect the positions and the shapes of the notched portions, such as notches or orientation flats, of the substrates 3a and 3b and the positions and the shapes of the push pins. The measurement unit 6a-3 can include an optical system and an imaging system.

The exposure module 7a of the processing station 101 is provided with the exposure unit 7a-1. The exposure unit 7a-1 can emit curing energy (for example, light such as UV light).

The substrate processing system 100 includes a control unit CNT. The control unit CNT can be configured by, for example, a Programmable Logic Device (PLD) such as a Field Programmable Gate Array (FPGA), an Application Specific Integrated Circuit (ASIC), a general-purpose or dedicated computer installed with a program, or a combination of all or some of these components.

For example, the control unit CNT can be configured to control the execution of a shaping process such as a planarization process. The planarization process is an example of a shaping process of shaping a curable composition on the substrate 3 and is a process of forming a film having a planarized surface using the cured product of the curable composition. More specifically, the planarization process is a process of performing planarization of the curable composition by bringing the flat surface of the mold 1 into contact with the curable composition on the substrate 3 and making the curable composition conform to the surface shape of the substrate 3. The planarization process is generally performed for each lot, that is, each of a plurality of substrates included in the same lot.

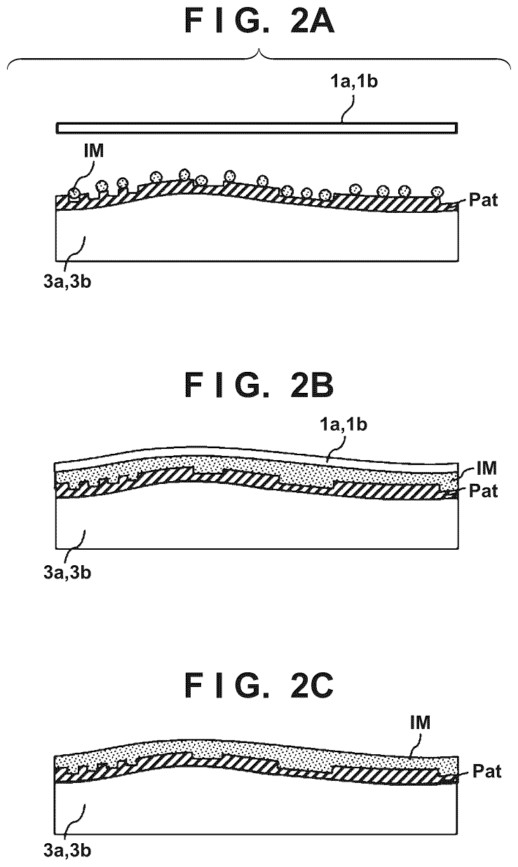

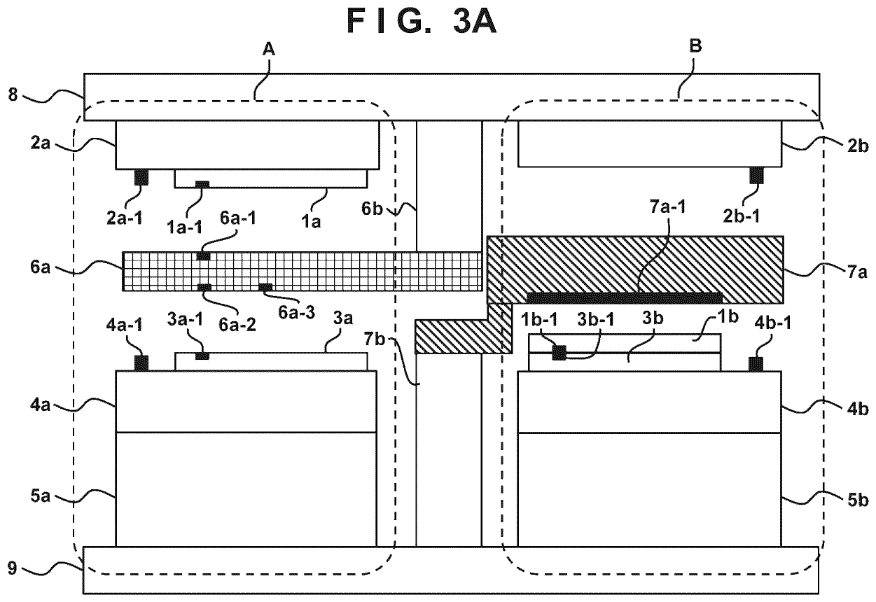

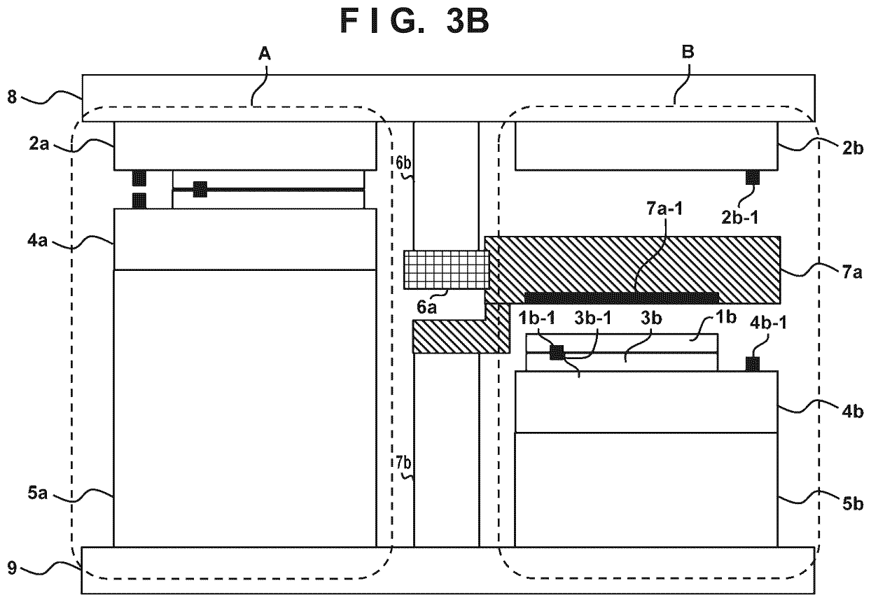

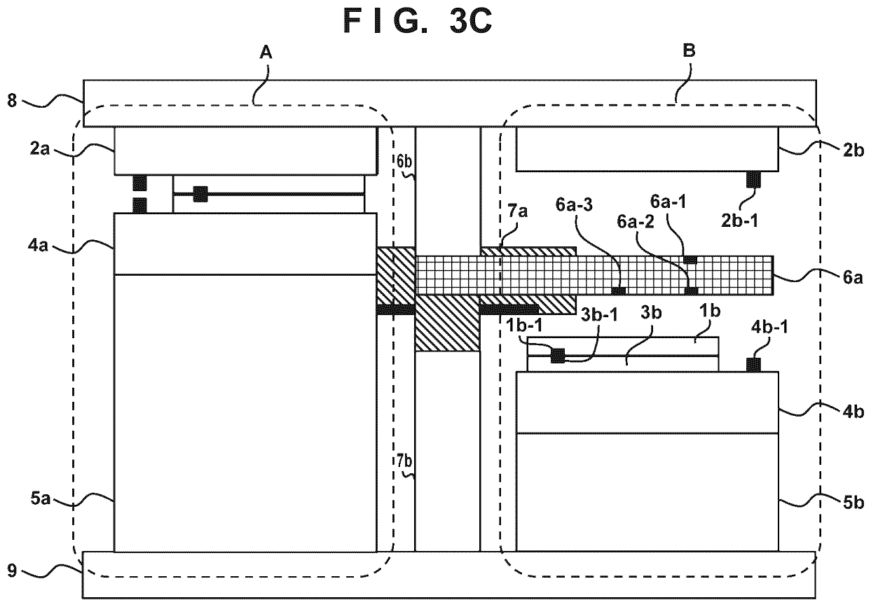

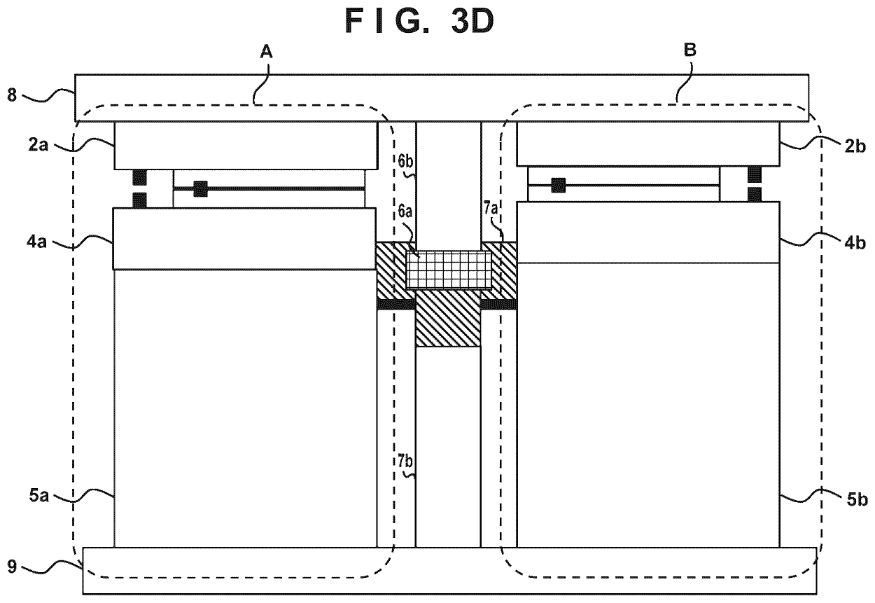

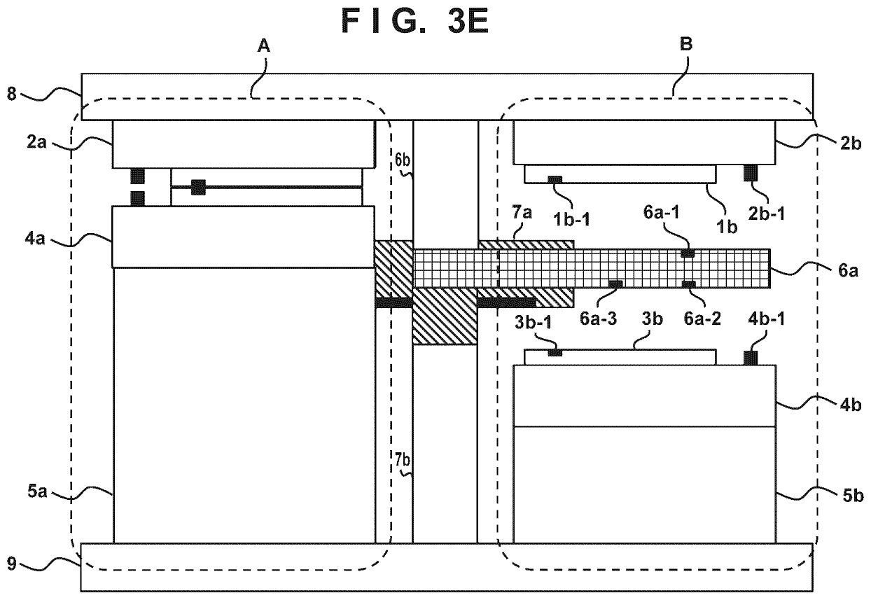

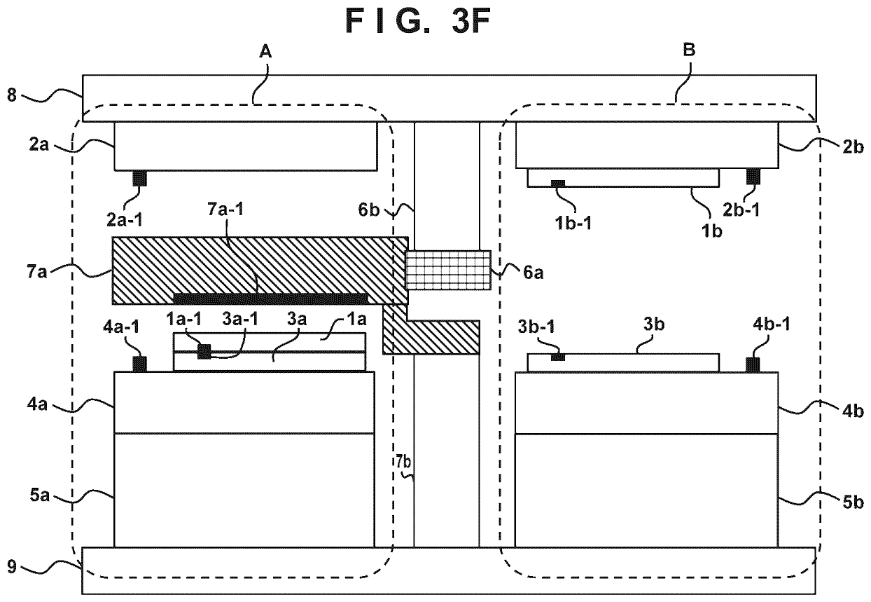

An outline of the planarization process will be described below with reference to FIGS. 2A to 2C and FIGS. 3A to 3F. FIGS. 2A to 2C exemplarily show a procedure for the planarization process. FIGS. 3A to 3F exemplarily show the operation of the substrate processing system 100 in the planarization process. First of all, in the step shown in FIG. 2A, the dispenser 10 of the processing station 102 supplies or arranges curable compositions IM onto the substrates 3a and 3b which have base patterns Pat. FIG. 2A exemplarily shows a state before the molds 1a and 1b are brought into contact with the curable compositions IM after the curable compositions IM are supplied onto the substrates 3a and 3b. The conveying robot 15 then conveys the substrates 3a and 3b from the processing station 102 to the processing station 101.

The subsequent operation of operation module A of operation modules A and B of the processing station 101 will be described first. As schematically shown in FIG. 3A, the first pivot mechanism 6b makes the measurement module 6a pivot so as to arrange the measurement module 6a at a position in the +Z direction with respect to the substrate 3a and in the −Z direction with respect to the mold 1a. Next, positioning is executed between the substrate 3a and the mold 1a by using the measurement module 6a. In this case, it is possible to measure at least one of the followings by using the measurement unit 6a-2: the position of the substrate reference mark 4a-1 provided on the stage of the substrate fine moving stage mechanism 4a, the position of the substrate mark 3a-1, and the shape of the substrate 3a. In addition, it is possible to detect one of the followings by using the measurement unit 6a-1: the position of the mold reference mark 2a-1 provided on the mold head 2a, the position of the mold mark 1a-1 provided on the mold 1a, and the shape of the mold 1a. Positioning can be executed between the notched portion of the substrate 3a and the push pin by using the measurement unit 6a-3. In this case, the order of measuring operations by the measurement units 6a-1, 6a-2, and 6a-3 is arbitrary. In addition, the measuring operations of the measurement units 6a-1, 6a-2, and 6a-3 may be executed a plurality of times. Furthermore, the measuring operations of the measurement units 6a-1, 6a-2, and 6a-3 may be executed during the pivoting movement of the measurement module 6a or after the stoppage of the pivoting movement.

A positional shift between the substrate 3a and the mold 1a can be detected by measuring the positions of a mark on the substrate 3 and a mark on the mold 1a using the measurement module 6a. Alternatively, a positional shift between the substrate 3a and the mold 1a can be detected by measuring the shapes of the end portions of the substrate 3 and the mold 1a based on the images of the end portions using the measurement module 6a. Alternatively, a positional shift between the substrate 3a and the mold 1a can be detected by measuring the shape of the end portion of the substrate 3 using displacement sensors or height sensors as the measurement units 6a-1 and 6a-2. The substrate fine moving stage mechanism 4a can then position the substrate 3a and the mold 1a by positioning the substrate 3a so as to cancel out the positional shift.

A positional shift between the notched portion of the substrate 3a and the push pin can be detected by measuring the position of a mark on the substrate 3 or the shape of the end portion of the substrate 3 based on images of them using the measurement module 6a. Alternatively, a positional shift between the notched portion of the substrate 3a and the push pin can be detected by measuring the shape of the end portion of the substrate 3 using a displacement sensor or a height sensor as the measurement unit 6a-2. The substrate fine moving stage mechanism 4a, which can be driven independently of the push pin, can then position the notched portion of the substrate 3a and the push pin by positioning the substrate 3a so as to cancel out the positional shift. FIG. 3A schematically shows operation module A in this state.

Next, as schematically shown in FIG. 3B, the first pivot mechanism 6b causes the measurement module 6a to retreat from operation module A. Subsequently, the substrate coarse moving stage mechanism 5a drives the substrate fine moving stage mechanism 4a (the substrate 3a) in the +Z direction. The mold head driving unit then adjusts the distance between the substrate 3a and the mold 1a so as to bring the mold 1a held by the mold head 2a into contact with the curable composition IM on the substrate 3a (contact step). FIG. 2B schematically shows such a contact step. The mold head 2a then releases the holding of the mold 1a, and the substrate fine moving stage mechanism 4a drives the stack of the substrate 3a, the curable composition IM, and the mold 1a in the −Z direction, thereby forming a space on the stack in which the exposure module 7a can pivot.

Subsequently, as schematically shown in FIG. 3F, the second pivot mechanism 7b makes the exposure module 7a pivot to arrange the exposure module 7a on the stack of the substrate 3a, the curable composition IM, and the mold 1a. The curable composition IM on the substrate 3a is then irradiated with curing energy through the mold 1a, thereby curing the curable composition IM (curing step).

The operation of operation module B will be described below. In the states shown in FIGS. 3A and 3B, in operation module B, the exposure module 7a irradiates the curable composition IM between the substrate 3b and the mold 1b with curing energy, thereby curing the curable composition IM (curing step).

As schematically shown in FIG. 3C, the second pivot mechanism 7b makes the exposure module 7a pivot to make the exposure module 7a retreat from above the mold 1b. The first pivot mechanism 6b then causes the measurement module 6a to pivot so as to arrange the measurement module 6a at a position in the +Z direction with respect to the substrate 3b and in the −Z direction with respect to the mold 1b.

The mold 1b and the mold head 2b are positioned by using the measurement module 6a. In this case, it is possible to measure at least one of the followings by using the measurement unit 6a-2: the substrate reference mark 4b-1 provided on the stage of the substrate fine moving stage mechanism 4b, the substrate mark 3b-1, the shape of the substrate 3b, the mold mark 1b-1 provided on the mold 1b, and the shape of the mold 1b. In addition, it is possible to measure the position of the mold reference mark 2b-1 provided on the mold head 2b by using the measurement unit 6a-1. This makes it possible to detect a positional shift between the mold 1b and the mold head 2b. The substrate fine moving stage mechanism 4a can then position the stack of the substrate 3b, the curable composition IM, and the mold 1b and the mold head 2b by positioning the stack (the mold 1b) so as to cancel out the positional shift. The first pivot mechanism 6b causes the measurement module 6a to pivot to make the measurement module 6a retreat from above the mold 1b.

As schematically shown in FIG. 3D, the substrate coarse moving stage mechanism 5b drives the substrate fine moving stage mechanism 4b (the substrate 3b) in the +Z direction. The mold head driving unit then adjusts the distance between the substrate 3b and the mold 1b so as to separate the mold 1b from the cured product of the curable composition IM on the substrate 3b (separation step). This makes it possible to form the planarized cured product of the curable composition IM on the substrate 3b. FIG. 2C schematically shows the substrate 3b after the separation step and the planarized cured product of the curable composition IM.

As schematically shown in FIG. 3E, the first pivot mechanism 6b causes the measurement module 6a to pivot so as to arrange the measurement module 6a at a position in the +Z direction with respect to the substrate 3b and in the −Z direction with respect to the mold 1b. In this state, a neutralization unit (not shown) provided in the measurement module 6a can perform neutralization.

As schematically shown in FIG. 3F, the first pivot mechanism 6b causes the measurement module 6a to retreat from operation module B. The conveying robot 15 then unloads the substrate 3b. At this time, when the measurement module 6a does not interfere with the conveying robot 15, the substrate 3b may be unloaded without retreat of the measurement module 6a.

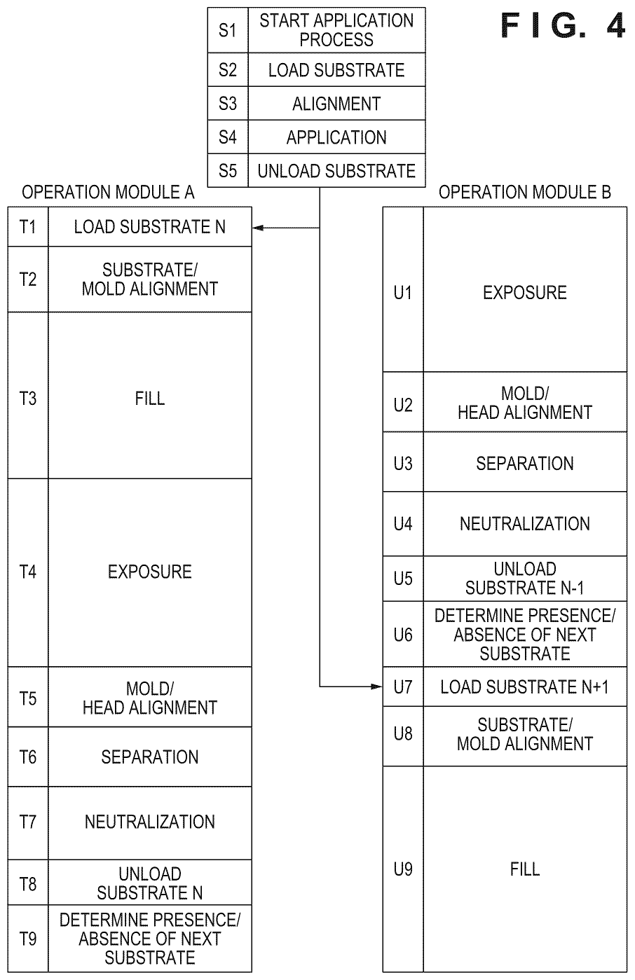

FIG. 4 shows the operation of the substrate processing system 100 with focus on substrates N−1, N, and N+1. S1 to S5, T1 to T9, and U1 to U9 represent steps. The following is a description about steps after the substrates 3a and 3b are subjected to the processing from S1 to S6 in the processing station 102 and conveyed to the processing station 101. In order to describe the procedure of sequential processing for the substrates 3a and 3b, assume that the substrates 3a and 3b are the substrates N−1, N, and N+1. In this case, the substrates N−1, N, and N+1 processed by the processing station 102 are alternately loaded into operation module A and operation module B of the processing station 101 and concurrently processed. In addition, in this case, the measurement module 6a and the exposure module 7a are shared by operation module A and operation module B but are not simultaneously used in each step. In this case, the measurement module 6a and the exposure module 7a each can cope with a plurality of operation modules.

T1 to T9 represent steps to be executed by operation module A. In T1, the conveying robot 15 loads the substrate N unloaded from the processing station 102 into operation module A of the processing station 101. In T2, the first pivot mechanism 6b arranges the measurement module 6a in operation module A, positions the substrate N and the mold 1a by using the measurement module 6a, and executes positioning of the notched portion of the substrate N and the push pin. Thereafter, the first pivot mechanism 6b causes the measurement module 6a to retreat from operation module A. In T3, the substrate coarse moving stage mechanism 5a drives the substrate fine moving stage mechanism 4a (the substrate N) in the +Z direction. In addition, the mold head driving unit adjusts the distance between the substrate N and the mold 1a so as to bring the curable composition IM on the substrate N into contact with the mold 1a. This brings the mold 1a into contact with the curable composition on the substrate N and makes the mold 1a conform to the surface shape of the substrate N. In T4, the second pivot mechanism 7b arranges the exposure module 7a in operation module A, and the exposure module 7a irradiates the curable composition IM on the substrate N with curing energy through the mold 1a, thereby curing the curable composition IM (curing step). Subsequently, the second pivot mechanism 7b causes the exposure module 7a to retreat from the exposure module 7a. In T5, the first pivot mechanism 6b arranges the measurement module 6a in first operation module A and executes positioning of the mold head 2a and the mold 1a by using the measurement module 6a. In T6, the substrate coarse moving stage mechanism 5a drives the substrate fine moving stage mechanism 4a (the substrate N) in the +Z direction and drives the mold head 2a so as to separate the mold 1a from the cured product of the curable composition IM on the substrate N (separation step). In T7, the first pivot mechanism 6b causes the measurement module 6a to pivot to operation module A, and the neutralization unit (not shown) provided on the measurement module 6a executes neutralization. In T8, the substrate N processed in operation module A of the processing station 101 is unloaded. In T9, the presence/absence of a substrate to be processed next is checked. If there is a substrate to be processed next, the process returns to T1 to continue the processing. If there is no substrate to be processed next, the processing is terminated.

U1 to U9 represent steps executed in operation module B. In U1, the conveying robot 15 loads the substrate N+1 unloaded from the processing station 102 into operation module B of the processing station 101. In U2, the first pivot mechanism 6b arranges the measurement module 6a in operation module B and executes positioning between the substrate N+1 and the mold 1b and positioning between the notched portion of the substrate N+1 and the push pin by using the measurement module 6a. Thereafter, the first pivot mechanism 6b causes the measurement module 6a to retreat from operation module B. In U3, the substrate coarse moving stage mechanism 5b drives the substrate fine moving stage mechanism 4b (the substrate N+1) in the +Z direction. In addition, the mold head driving unit adjusts the distance between the substrate N+1 and the mold 1b so as to bring the curable composition IM on the substrate N+1 into contact with the mold 1b. This brings the mold 1b into contact with the curable composition on the substrate N+1 and makes the mold 1b conform to the surface shape of the substrate N+1. In U4, the second pivot mechanism 7b arranges the exposure module 7a in operation module B, and the exposure module 7a irradiates the curable composition IM on the substrate N+1 with curing energy through the mold 1b, thereby curing the curable composition IM (curing step). Subsequently, the second pivot mechanism 7b causes the exposure module 7a to retreat from operation module B. In U5, the first pivot mechanism 6b arranges the measurement module 6a in operation module B and executes positioning between the mold head 2b and the mold 1b by using the measurement module 6a. In U6, the substrate coarse moving stage mechanism 5b drives the substrate fine moving stage mechanism 4b (the substrate N) in the +Z direction, and the mold head 2b is driven to separate the mold 1b from the cured product of the curable composition IM on the substrate N+1 (separation step). In U7, the first pivot mechanism 6b causes the measurement module 6a to pivot to operation module B, and the neutralization unit (not shown) provided in the measurement module 6a executes neutralization. In U8, the substrate N+1 processed by operation module B of the processing station 101 is unloaded. In U9, the presence/absence of a substrate to be processed next is checked. If there is a substrate to be processed next, the process returns to U1 to continue the processing. If there is no substrate to be processed next, the processing is terminated.

As described above, the substrate processing system according to this embodiment includes a plurality of operation modules and one or a plurality of processing modules to be inserted/removed into/from each of the plurality of operation modules by a pivoting operation. One or a plurality of processing modules perform a process for shaping a curable composition on a substrate by using a mold in each of a plurality of operation modules. According to this arrangement, it is possible to simplify the arrangement of the substrate processing system that concurrently processes two or more substrates. In addition, it is possible to improve the productivity by using one or a plurality of processing modules in a plurality of operation modules at different timings.

An article manufacturing method according to one embodiment can include a step of forming a film made of the cured product of a curable composition on a substrate by using the substrate processing system 100 and a step of obtaining an article by processing the substrate on which the film is formed. This film can be a planarized film. Alternatively, the film can be a film onto which a pattern of a mold is transferred.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-085704, filed May 24, 2023, which is hereby incorporated by reference herein in its entirety.

What is claimed is:

1. A substrate processing system comprising:
a plurality of operation modules each configured to perform operations of bringing a curable composition on a substrate into contact with a mold and separating a cured product of the curable composition and the mold from each other; and
one or a plurality of processing modules configured to be inserted/removed into/from each of the plurality of operation modules by a pivoting operation,
wherein the one or the plurality of processing modules perform a process for shaping a curable composition on a substrate by using a mold in each of the plurality of operation modules, and
the process includes at least one of a chemical process and a measurement process.

2. The system according to claim 1, wherein the one or the plurality of processing modules include an exposure module configured to cure the curable composition and a measurement module configured to perform measurement for positioning a substrate and a mold.

3. The system according to claim 2, further comprising:
a first pivot mechanism configured to insert/remove the exposure module into/from each of the plurality of operation modules by a pivoting operation; and
a second pivot mechanism configured to insert/remove the measurement module into/from each of the plurality of operation modules by a pivoting operation.

4. The system according to claim 3, wherein one of the first pivot mechanism and the second pivot mechanism is arranged above the other of the first pivot mechanism and the second pivot mechanism.

5. The system according to claim 4, wherein the pivot axis of the first pivot mechanism and the pivot axis of the second pivot mechanism are arranged on the same straight line.

6. The system according to claim 3, wherein the first pivot mechanism and the second pivot mechanism independently perform pivoting operations.

7. The system according to claim 1, wherein each of the plurality of operation modules includes a stage mechanism configured to drive a substrate and a mold head configured to drive a mold.

8. The system according to claim 1, further comprising a plurality of pivot mechanisms configured to insert/remove the plurality of processing modules into/from each of the plurality of operation modules by a pivoting operation.

9. The system according to claim 8, wherein the pivot axes of the plurality of pivot mechanism are arranged on the same straight line.

10. The system according to claim 8, wherein each of the plurality of operation modules includes a stage mechanism configured to drive a substrate and a mold head configured to drive a mold, and
the plurality of pivot mechanisms arrange a processing module selected from the plurality of processing modules at a position between the stage mechanism and the mold head in each operation module.

11. The system according to claim 10, wherein the one or the plurality of processing modules include an exposure module configured to cure the curable composition and a measurement module configured to perform measurement for positioning a substrate and a mold.

12. The system according to claim 11, wherein a pivot mechanism of the plurality of pivot mechanisms which causes the exposure module to pivot arranges the exposure module at a position between the mold head and the stage mechanism holding a stack of a substrate, a curable composition, and a mold.

13. The system according to claim 11, wherein a pivot mechanism of the plurality of pivot mechanisms which causes the measurement module to pivot arranges the measurement module at a position between the stage mechanism and the mold head.

14. The system according to claim 11, wherein a pivot mechanism of the plurality of pivot mechanisms which causes the exposure module to pivot arranges the exposure module at a position between the mold head and the stage mechanism holding a stack of a substrate, a curable composition, and a mold.

15. The system according to claim 9, wherein a center of each of the plurality of operation modules is arranged on a circumference centered on a pivot axis of the plurality of pivot mechanisms.

16. The system according to claim 1, wherein a mold having a flat surface that comes into contact with a curable composition on a substrate is used as the mold to form a planarized film made of a cured product of a curable composition.

17. An article manufacturing method comprising:
forming a film made of a cured product of a curable composition on a substrate by using a substrate processing system defined in claim 1; and
obtaining an article by processing the substrate on which the film is formed.
